(19) United States
(12) Patent Application Publication
(10) Pub. No.: US 2013/0241616 A1
(43) Pub. Date: Sep. 19, 2013

(54) Keeper Circuit And Electronic Device Having The Same

(71) Applicant: Min Su KIM, Hwaseong-si (KR)

(72) Inventor: Min Su KIM, Hwaseong-si (KR)

(73) Assignee: SAMSUNG ELECTRONICS CO., LTD., Suwon-si (KR)

(21) Appl. No.: 13/618,049

(22) Filed: Sep. 14, 2012

(30) Foreign Application Priority Data
Mar. 16, 2012 (KR) 10-2012-0027242

(51) Int. Cl. H03K 3/356

(52) U.S. Cl. 327/208

(57) ABSTRACT

A keeper circuit includes a first latch and a second latch, each of the first latch and the second latch being configured to latch output data determined by input data during an evaluation phase, and the second latch, during a high-impedance phase, being configured to maintain output data of the second latch using output data of the first latch.

### CROSS-REFERENCE TO RELATED APPLICATIONS

This application claims priority under 35 U.S.C. §119(a) to Korean Patent Application No. 10-2012-0027242 filed on Mar. 16, 2012, the entire contents of which are hereby incorporated by reference.

### BACKGROUND

At least one example embodiment of inventive concepts relates to a keeper circuit, and more particularly, to a keeper circuit that may reduce (or alternatively, eliminate) data distortion caused by a coupling noise, even if a length of interconnection wire becomes long such that the wire is exposed to the coupling noise, and/or an electronic device including the same.

A design of latch or flip-flop operating at a high speed is necessary to design a chip operating at a high speed. A storage device including the latch or the flip-flop needs to store a specific logic value according to a cycle time of a clock signal. A latch node of the storing device may be composed of a capacitance load, but the latch node or the capacitance load is vulnerable to an external noise.

Thus, an inverter latch is connected to the latch node to maintain a logic value of the latch node. However, even though the inverter latch is connected to the latch node, if a length of interconnection wire of the latch node becomes long, the latch node may be influenced by an exterior coupling noise. Accordingly, the logic value stored to the storage device may be distorted or changed.

### SUMMARY

At least one example embodiment of the inventive concepts provides a keeper circuit including a first latch; and a second latch, each of the first latch and the second latch being configured to latch output data determined by input data during an evaluation phase, and the second latch, during a high-impedance phase, being configured to maintain output data of the second latch using output data of the first latch.

According to at least one example embodiment, the first latch includes a first inverter configured to invert the input data during the evaluation phase, a second inverter connected to an output node of the first inverter, and a third inverter connected between an output node of the second inverter and the output node of the first inverter.

According to at least one example embodiment, the second latch includes a fourth inverter configured to invert the input data during the evaluation phase, a fifth inverter connected between the output node of the second inverter and an output node of the fourth inverter. The third inverter and the fifth inverter are disabled during the evaluation phase and enabled in the high-impedance phase.

According to at least one example embodiment, the first latch includes a first inverter configured to determine latch node data based on the input data and a clock signal, a second inverter configured to invert the latch node data, and a third inverter configured to latch the latch node data based on an output signal of the second inverter and the clock signal.

According to at least one example embodiment, the second latch includes a fourth inverter configured to determine the output data of the second latch based on the input data and the clock signal and a fifth inverter configured to latch the output data of the second latch based on an output signal of the second inverter and the clock signal.

According to at least one example embodiment, the first inverter and the fourth inverter are enabled, and the third inverter and the fifth inverter are disabled during the evaluation phase. The first inverter and the fourth inverter are disabled, and the third inverter and the fifth inverter are enabled during the high-impedance phase.

According to at least one example embodiment, the inventive concepts provide an electronic device including a processor, the processor including a keeper circuit and a wireless network interface connected to the processor through an interface control block.

According to at least one example embodiment, the keeper circuit includes a first latch; and a second latch, each of the first latch and the second latch being configured to latch output data determined by input data during an evaluation phase, and the second latch, during a high-impedance phase, being configured to maintain output data of the second latch using output data of the first latch.

According to at least one example embodiment, the processor further includes a dynamic logic circuit configured to determine a logic level of the input data based on a clock signal and data. The electronic device may be a system on chip or a computing system.

According to at least one example embodiment, a circuit comprises: a first latch configured to output a first signal based on at least one input signal during a first phase; and a second latch configured to output a second signal of the second latch during the first phase, and maintain the second signal during a second phase according to the first signal.

According to at least one example embodiment, the first and second phases correspond to a storing operation of a memory element.

According to at least one example embodiment, if the at least one input signal is a logic state ‘1’, then the second latch maintains the second signal at a logic state ‘0’ during the second phase.

According to at least one example embodiment, if the at least one input signal is a logic state ‘0’, then the second latch maintains the second signal at a logic state ‘1’ during the second phase.

According to at least one example embodiment, the first latch includes first and second logic gates and an inverter, and the second latch includes third and fourth logic gates.

According to at least one example embodiment, an input of the first logic gate and an input of the third logic gate are configured to receive the at least one input signal, an output of the first logic gate is connected to an output of the second logic gate and an input of the inverter, an output of the inverter is connected to an input of the second logic gate and an input of the fourth logic gate, and an output of the third logic gate is connected to an output of the fourth logic gate, and the third logic gate is configured to output the second signal during the first phase and the fourth logic gate is configured maintain the second signal during the second phase.

### BRIEF DESCRIPTION OF THE DRAWINGS

FIG. 1 is a block diagram of a keeper circuit according to at least one example embodiment of the inventive concepts;

FIG. 2 is an example embodiment of the keeper circuit illustrated in FIG. 1;

FIG. 3 is another example embodiment of the keeper circuit illustrated in FIG. 1;

FIGS. 4A through 4D are example embodiments of a three-state logic gate illustrated in FIG. 2 or 3;

FIG. 5 is another example embodiment of the keeper circuit illustrated in FIG. 5;

FIG. 6 is a block diagram of a data processing circuit including a keeper circuit according to at least one example embodiment of the inventive concepts;

FIG. 7 is a circuit diagram showing an example embodiment of the data processing circuit illustrated in FIG. 6;

FIGS. 8 through 12 are example embodiments of a dynamic logic circuit illustrated in FIG. 6 or 7;

FIG. 13 is a block diagram of an electronic device including the keeper circuit according to at least one example embodiment of the inventive concepts; and

FIG. 14 is a flow chart for explaining an operation of the keeper circuit according to at least one example embodiment of the inventive concepts.

### DETAILED DESCRIPTION OF EXAMPLE EMBODIMENTS

Example embodiments will be understood more readily by reference to the following detailed description and the accompanying drawings. Example embodiments may, however, be embodied in many different forms and should not be construed as being limited to those set forth herein. Rather, these example embodiments are provided so that this disclosure will be thorough and complete. Example embodiments should be defined by the appended claims. In at least some example embodiments, well-known device structures and well-known technologies will not be specifically described in order to avoid ambiguous interpretation.

It will be understood that when an element is referred to as being “connected to” or “coupled to” another element, it can be directly on, connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of example embodiments.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises,” “comprising,” “includes,” and/or “including” when used in this specification, specify the presence of stated components, steps, operations, and; or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

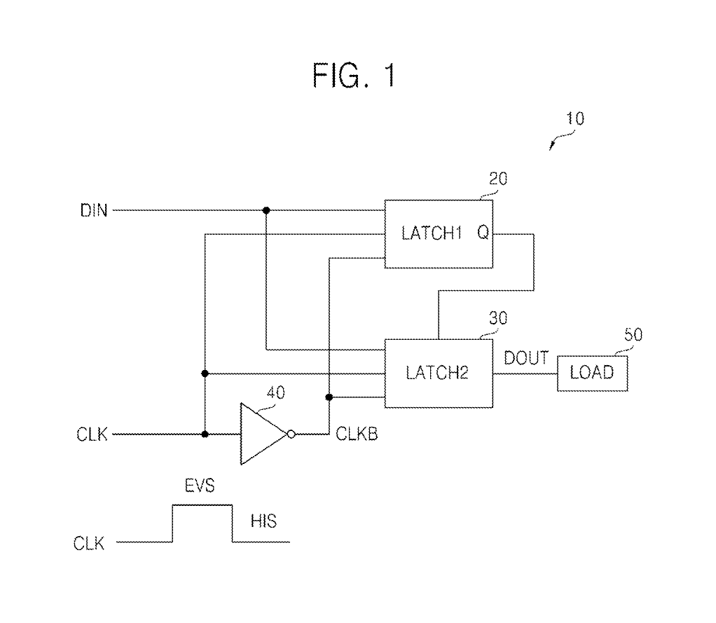

FIG. 1 is a block diagram of a keeper circuit according to at least one example embodiment of the inventive concepts. Referring to FIG. 1, the keeper circuit 10 includes a first latch 20, a second latch 30, and an inverter 40.

The keeper circuit 10 may be used in a circuit capable of storing data, such as a latch circuit, flip-flop, or register.

The first latch 20 latches or outputs output data determined by input data DIN, for example, latch node data, in an evaluation state EVS. The second latch 30 latches or outputs output data DOUT determined by the input data DIN, for example, a latch data, in the evaluation state EVS.

The first latch 20 maintains the latch node data of the first latch 20 in a high-impedance state HIS. The second latch 30 maintains the output data DOUT of the second latch 30 by using output data of the first latch 20, for example, data output through output node Q, in the high-impedance state HIS. The inverter 40 inverts a clock signal CLK and outputs an inverted clock signal CLKB.

The evaluation state EVS (also referred to as the evaluation phase) denotes that the clock signal CLK is a high level, and the high-impedance state HIS (also referred to as the high-impedance phase) denotes that the clock signal CLK is a low level. Unless delay of the inverter 40 is considered, the clock signal CLK and the inverted clock signal CLKB are complementary signals. The evaluation phase and the high-impedance phase may correspond to an operation of a processor that stores data to a memory element.

The keeper circuit 10 may further include a load 50 which is driven in response to the output data DOUT of the second latch 30. For example, the load 50 may be a bus or other logic circuit.

FIG. 1 illustrates that the inverter 40 is in the exterior of each of the latches 20 and 30, but the inverter 40 may be embodied in the inside of each of the latches 20 and 30, separately, according to at least one other example embodiment.

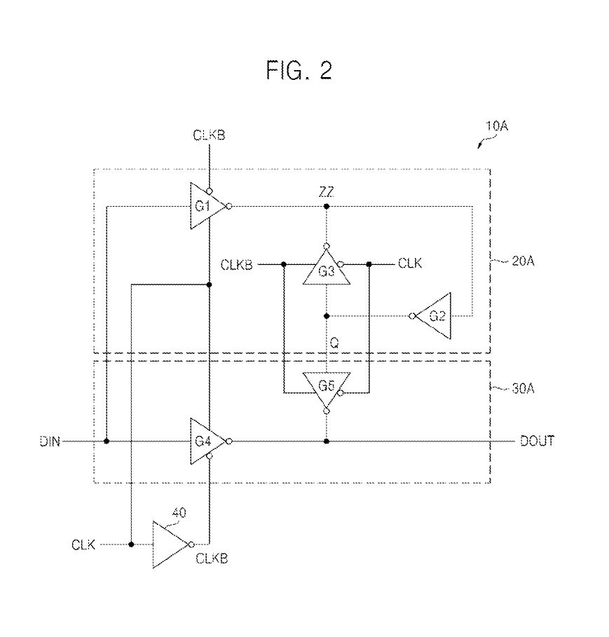

FIG. 2 illustrates an example embodiment of the keeper circuit illustrated in FIG. 1. Referring to FIGS. 1 and 2, a keeper circuit 10A includes a first latch 20A, a second latch 30A, and the inverter 40.

During the evaluation state EVS, each of three-state logic gates G1 and G4 are enabled, and each of three-state logic gates G3 and G5 are disabled.

The first logic gate G1 inverts the input data DIN in response to the clock signal CLK having a high level and the inverted clock signal CLKB having a low level, the inverter G2 inverts latch node data ZZ, and the fourth logic gate G4 inverts the input data DIN in response to the clock signal CLK having a high level and the inverted clock signal CLKB having a low level.

During the high-impedance state HIS, each of three-state logic gates G1 and G4 are disabled, and each of three-state logic gates G3 and G5 are enabled. Accordingly, each of the three-state logic gates G3 and G5 inverts output data of the inverter G2. For example, when the input data DIN is a high level during the evaluation state EVS, the output data ZZ and DOUT of each of the logic gates G1 and G4 are low levels, and the output data of the inverter G2 is a high level.

Each of the three-state logic gates G3 and G5 outputs each of the data ZZ and DOUT having a low level, respectively. The first latch 20A latches the output data ZZ of the first logic gate G1, and the second latch 30A maintains the output data DOUT of the second latch 30A by using the output data ZZ of the first logic gate G1 in the high-impedance state HIS.

Thus, even if a strong noise (e.g., a strong coupling noise) is input through an output node of the second latch 30A or an interconnection wire connected to the output node, the second latch 30A may maintain the output data DOUT of the second latch 30A according to the output data ZZ of the first logic gate G1.

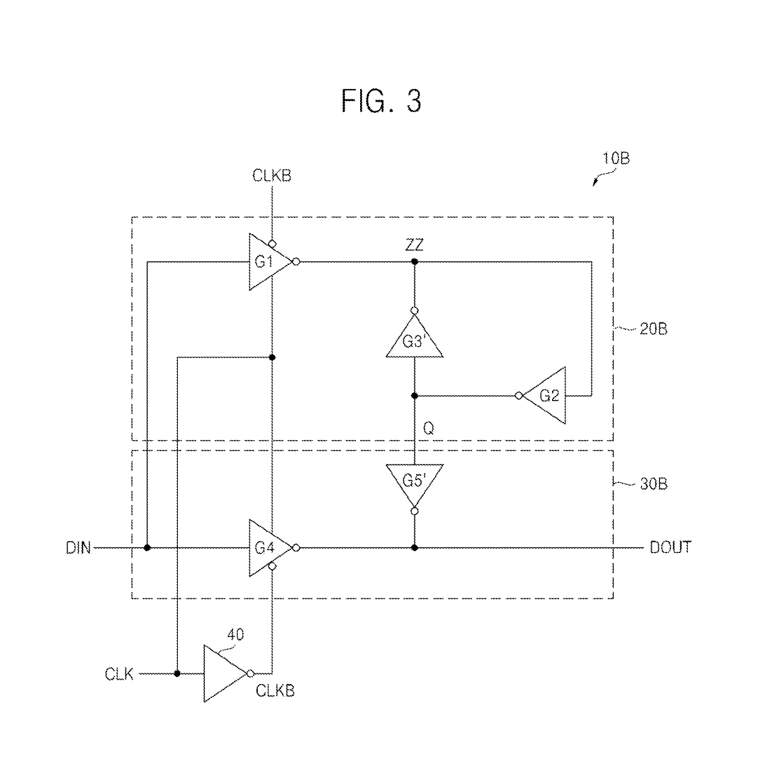

FIG. 3 illustrates another example embodiment of the keeper circuit illustrated in FIG. 1. Referring to FIGS. 2 and 3, an operation of the keeper circuit 10A of FIG. 2 and an operation of the keeper circuit 10B are similar, except that each of three-state logic gates G3 and G5 is replaced by each of inverters G3′ and G5′.

During the evaluation state EVS, for example, when the clock signal CLK is a high level and the inverted clock signal CLKB is a low level, and when the input data DIN is a high level, then the output data ZZ and DOUT of each of the logic gate G1 and G4 are a low level, output data of the inverter G2 is a high level, and output data of each inverter G3′ and G5′ is a low level.

During the high-impedance state EVS, for example, when the clock signal CLK is a low level, and the inverted clock signal CLKB is a high level, the output data of each inverter G3′ and G5′ maintain a low level. As described above, even though a strong noise (e.g., a strong coupling noise) is input through the output node of the second latch 30A or the interconnection wire connected to the output node, the second latch 30A may maintain the output data DOUT of the second latch 30A according to the output data ZZ of the first logic gate G1.

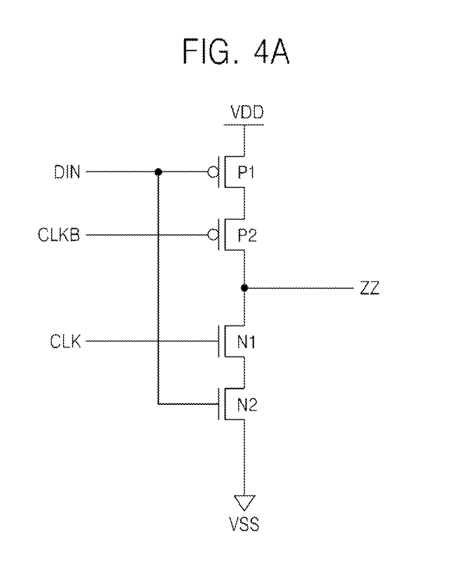

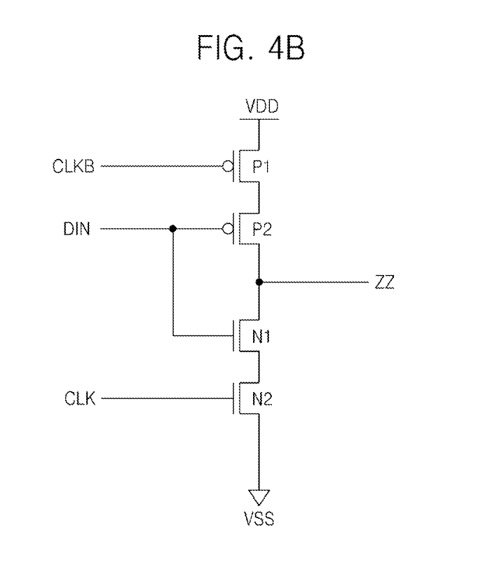

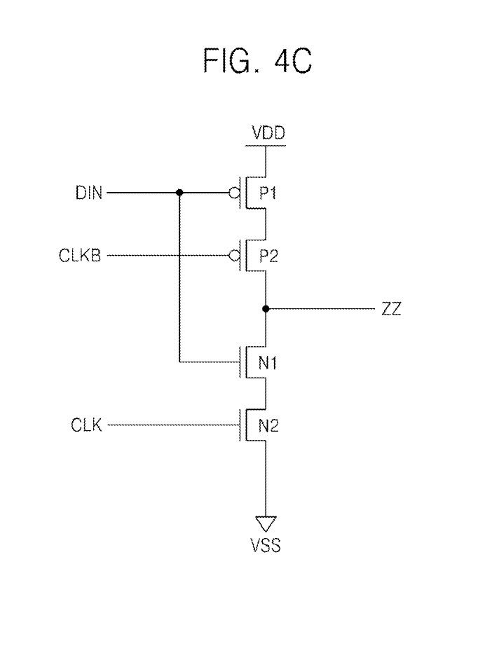

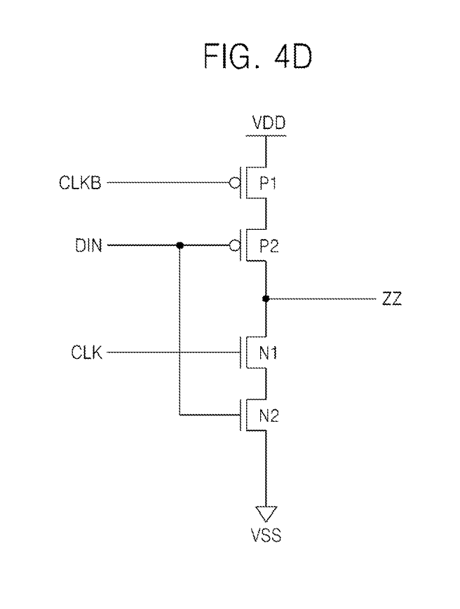

FIGS. 4A through 4D illustrate example embodiments of the three-state logic gates illustrated in FIG. 2 or 3.

Referring to FIG. 4A, the input data DIN is input to a gate of each MOS transistor P1 and N2, the inverted clock signal CLKB is input to a gate of a MOS transistor P2, and the clock signal CLK is input to a gate of a MOS transistor N1. Referring to FIG. 4B, the input data DIN is input to a gate of each MOS transistor P2 and N1, the inverted clock signal CLKB is input to a gate of a MOS transistor P1, and the clock signal CLK is input to a gate of a MOS transistor N2.

Referring to FIG. 4C, the input data DIN is input to a gate of each MOS transistor P1 and N1, the inverted clock signal CLKB is input to a gate of a MOS transistor P2, and the clock signal CLK is input to a gate of a MOS transistor N2. Referring to FIG. 4D, the input data DIN is input to a gate of each MOS transistor P2 and N2, the inverted clock signal CLKB is input to a gate of a MOS transistor P1, the clock signal CLK is input to a gate of MOS transistor N1.

Referring to FIGS. 4A through 4D, each of the three state logic gates operates as an inverter in the evaluation state EVS. Data ZZ of the output node of each three-state logic gate is floating in the high-impedance state HIS.

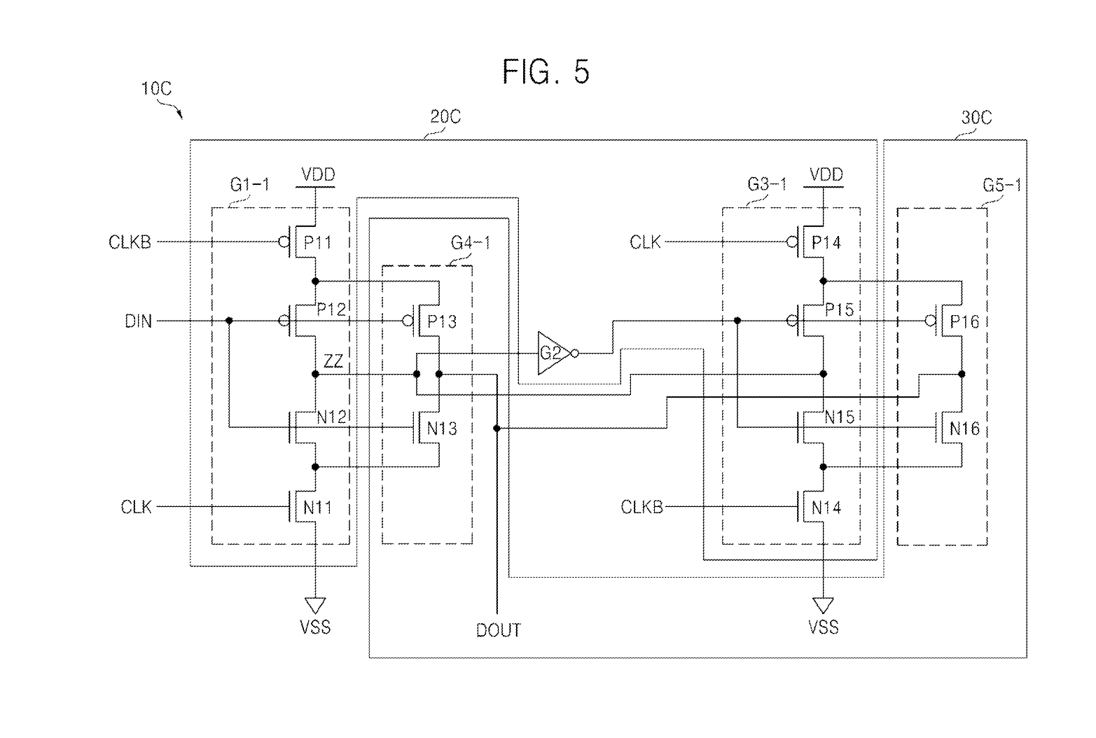

FIG. 5 illustrates another example embodiment of the keeper circuit illustrated in FIG. 1. Referring to FIG. 5, a keeper circuit 10C includes a first latch 20C including each logic gate G1-1, G2 and G3-1, and a second latch 30C including each logic gate G4-1 and G5-1.

Each latch 20C and 30C latches each output data ZZ and DOUT determined by input data DIN during the evaluation state. The second latch 30C maintains the output data DOUT of the second latch 30C by using the output data of the first latch 20C, for example, output data of an inverter G2, during the high-impedance state.

The first logic gate G1-1 includes MOS transistors P11, P12, N12, and NI1 connected between a power node receiving a power voltage VDD and a ground in series. In at least one example embodiment, the first logic gate G1-1 may perform a function of a tri-state inverter. The first logic gate G1-1 performs a function of an inverter inverting the input data DIN during the evaluation state.

The second logic gate G2 may be an inverter.

The third logic gate G3-1 includes MOS transistors P14, P15, N15, and N14 connected between the power node and the ground in series. In at least one example embodiment, the three logic gate G3-1 may perform a function of a tri-state inverter. The third logic gate G3-1 performs a function of an inverter inverting output data of the second inverter G2 during the high-impedance state.

The fourth logic gate G4-1 includes transistors P13 and N13 connected between a common node of the transistors P11 and P12 and a common node of the transistors N12 and N11 in series. The fourth logic gate G4-1 performs a function of an inverter inverting the input data DIN during the evaluation state.

The fifth logic gate G5-1 includes transistors P16 and N16 connected between a common node of the transistors P14 and P15 and a common node of the transistors N15 and N14. The fifth logic gate G5-1 performs a function of an inverter inverting output data of the second inverter G2 during the high-impedance state.

When the input data DIN is a high level during the evaluation state, the output data ZZ and DOUT of each of the logic gates G1-1 and G4-1 are in a low level, and the output data of the inverter G2 is a high level. At this time, each of the logic gates G3-1 and G5-1 is disabled.

During the high-impedance state, each of the logic gates G1-1 and G4-1 is disabled, and each of the logic gates G3-1 and G5-1 is enabled. Thus, as the logic gate G3-1 operates, the output data ZZ maintains a low level, and as the logic gate G5-1 operates, the output data DOUT maintains a low level.

When the input data DIN is a low level during the evaluation state, the output data ZZ and DOUT of each of the logic gates G1-1 and G4-1 are in a high level, the output data of the inverter G2 is a low level. At this time, each of the logic gates G3-1 and G5-1 is disabled.

During the high-impedance state, each of the logic gates G1-1 and G4-1 is disabled, and each of the logic gates G3-1 and G5-1 is enabled. Accordingly, as the logic gate G3-1 operates, the output data ZZ maintains a high level, as the logic gate G5-1 operates, the output data DOUT maintains a high level.

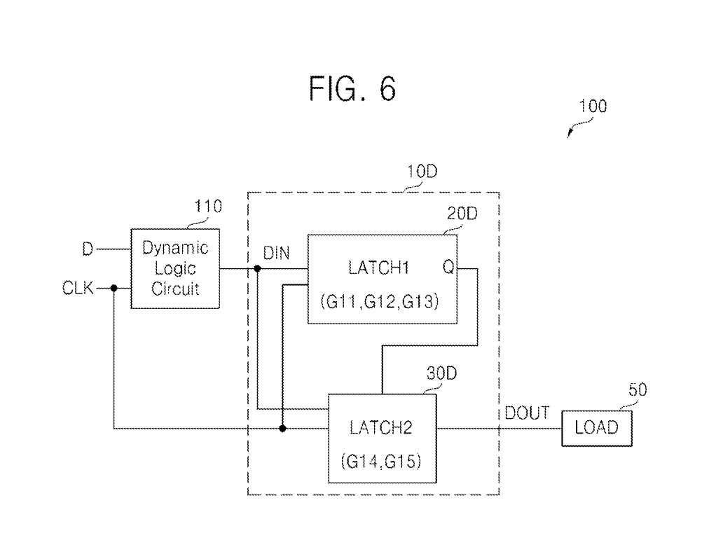

FIG. 6 illustrates a block diagram of a data processing circuit including a keeper circuit according to at least one example embodiment of the inventive concepts. Referring to FIG. 6, the data process circuit 100 includes a dynamic logic circuit 110 and a keeper circuit 10D. The data processing circuit 100 may further include a load 50 which is driven by output data DOUT of a second latch 30D.

The data processing circuit 100 may be an integrated circuit or system on chip (SoC). The dynamic logic circuit 110 referred to as a clocked logic may determine a logic level of the input data DIN based on the clock signal CLK and data D.

The dynamic logic circuit 110 may be a domino logic circuit or a semi-dynamic flip-flop.

During the evaluation state, each of latches 20D and 30D latches the output data ZZ and DOUT determined by the input data DIN, respectively. The second latch 30D maintains the output data DOUT of the second latch 30D by using the output data of the first latch 20D.

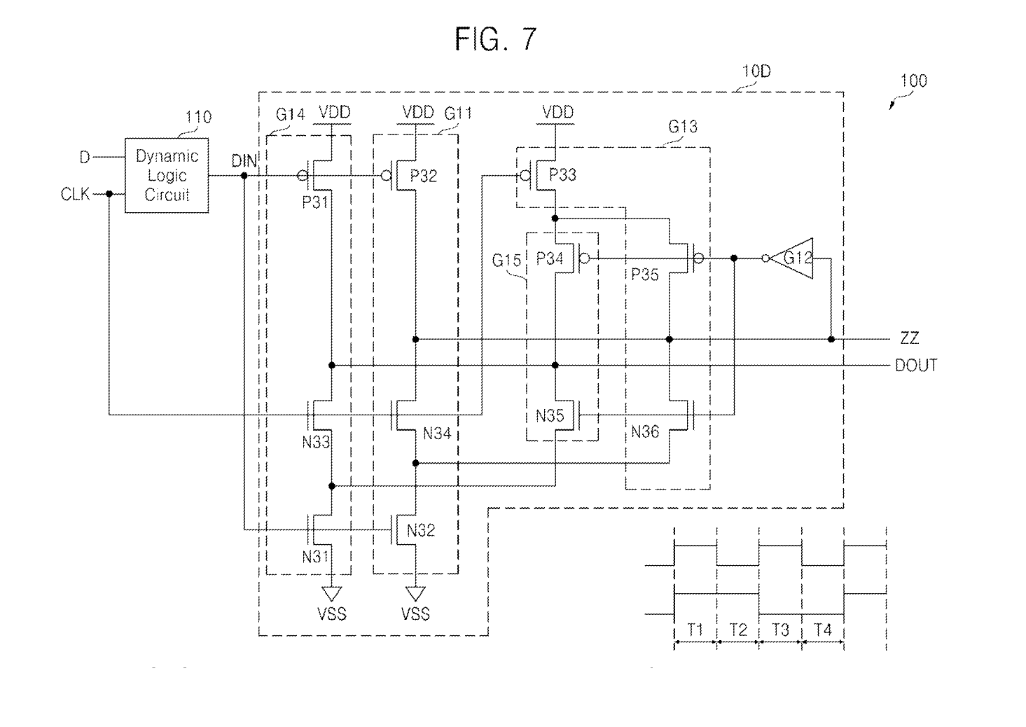

FIG. 7 is a circuit diagram illustrating an example embodiment of the data processing circuit illustrated in FIG. 6. Referring to FIGS. 6 and 7, the first latch 20D includes the logic gates G11, G12, and G13, and the second latch 30D includes the logic gates G14 and G15.

The first logic gate G11 includes MOS transistors P32 N34, and N32 connected between a power node receiving a power voltage VDD and a ground in series. The second logic gate G12 may be an inverter.

The third logic gate G13 includes MOS transistors P33, P35, and N36 connected to the power node and a common node of the transistors N34 and N32. The fourth logic gate G14 includes MOS transistors P31, N33, and N 31 connected between the power node and the ground in series. The fifth logic gate G15 includes transistors P34 and N35 connected between a common node of the transistors P33 and P 35 and a common node of the transistors N33 and N31.

When the input data DIN is a high level during the evaluation state EVS (that is, during T1 period), each of the transistors P31, P32, and P33 is turned-off and each of the transistors N31 to N34 is turned-on. Thus, the output data ZZ and DOUT of each of the logic gates G11 and G14 are in a low level.

Output data of the inverter G12 is a high level, accordingly, each of the transistors P34 and P35 is turned-off, and each of the transistors N35 and N36 is turned-on. Thus, each of the output data ZZ and DOUT maintains a low level.

When the input data DIN is a high level during the high-impedance state HIS (that is, during T2 period), even if each of the transistors N33 and N34 is turned-off, each of the transistors N31, N32, N35, and N36 maintains a turned-on state, thus, each of the output data ZZ and DOUT maintains a low level.

As described above, the transistor N35 of the fifth logic gate G15 of the second latch 30D is turned-on based on the output data of the inverter G12, thus, the second latch 30D may maintain the output data DOUT having a low level.

When the input data DIN is a low level during the evaluation state EVS (that is, during T3 period), each of the transistors N31, N32, and P33 is turned-off, and each of the transistors P31, P32, N33, and N34 is turned-on. Accordingly, the output data ZZ and DOUT of each logic gate G11 and G14 are in a high level.

As the output data of the inverter G12 is a low level, each of the transistors N35 and N36 is turned-off. At this time, the transistor P33 maintains a turned-off state.

When the input data DIN is a low level during the high-impedance state HIS (that is, during T4 period), the transistor P33 is turned-on. Accordingly, each of the transistors P33, P34, and P35 is turned-on, thus, each of the output data ZZ and DOUT maintains a high level.

As described above, the transistor P34 of the fifth logic gate G15 of the second latch 30D is turned-on according to the output data of the inverter G12, thus, the second latch 30D may maintain the output data DOUT having a high level.

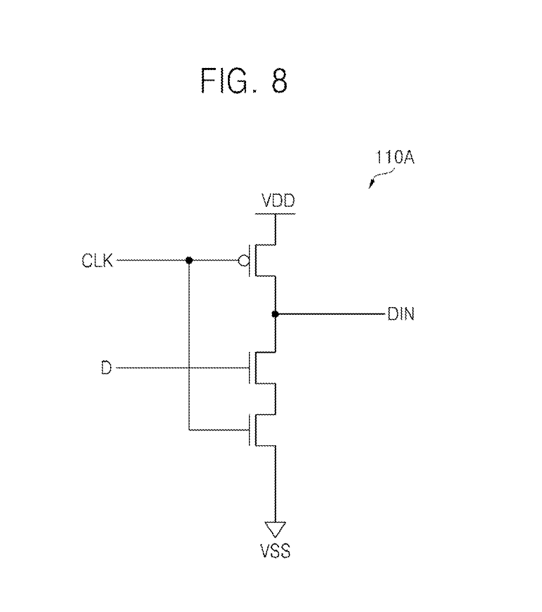

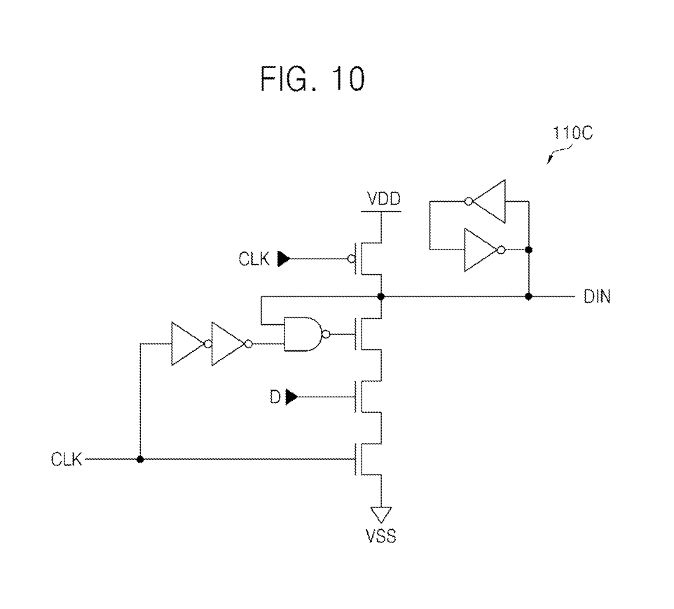

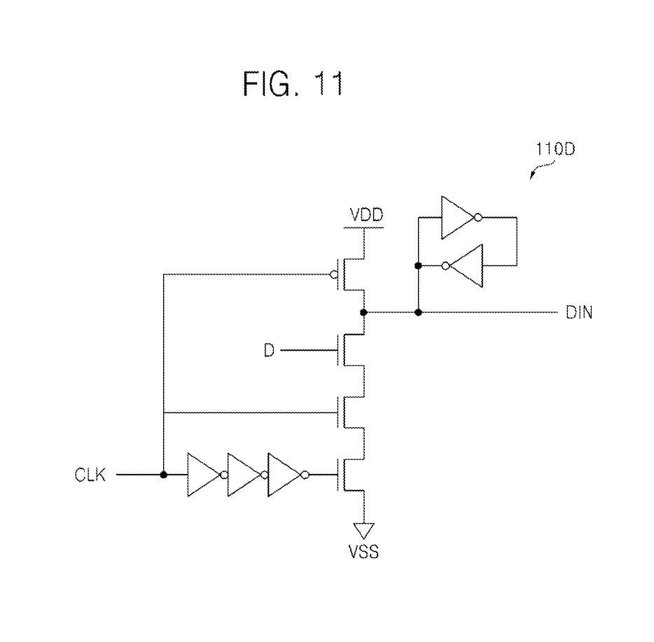

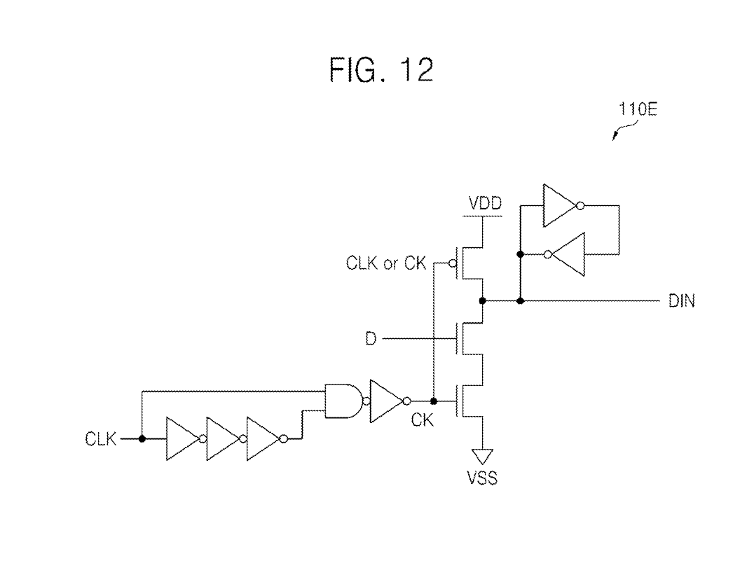

FIGS. 8 through 12 illustrate example embodiments of the dynamic logic circuit illustrated in FIG. 6 or 7. The dynamic logic circuit 110A illustrated in FIG. 8 is an example of a domino logic circuit.

When a clock signal CLK is a low level, that is, in a pre-charge phase, data DIN of a dynamic node is a high level. But, when the clock signal CLK is a high level, that is, in the evaluation phase, the data DIN of a dynamic node is a high level. Data of the dynamic node is determined by data D. For example, when the data D is a low level, the data DIN maintains a high level, and when the data D is a high level, the data DIN transits or switches to a low level.

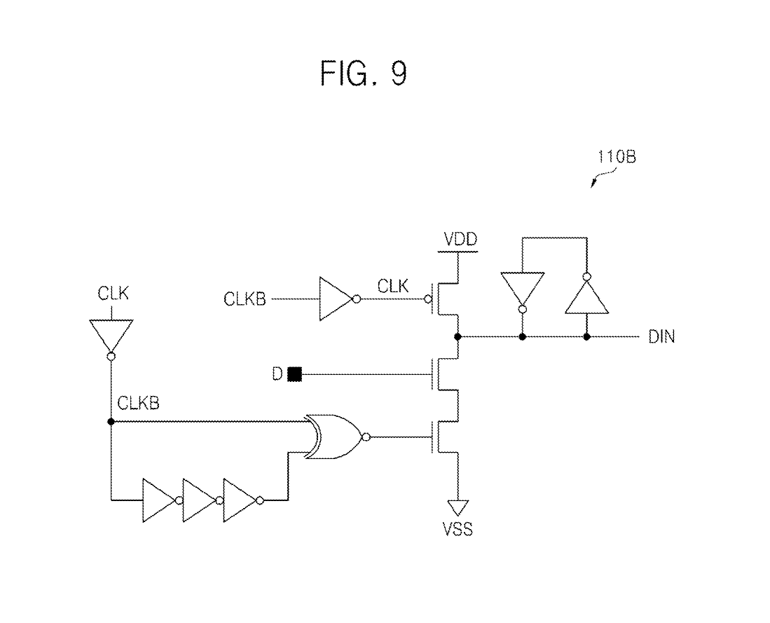

Each of dynamic logic circuits 110B, 110C, 110D, or 110E shown in FIGS. 9 through 12 illustrates an example of a semi-dynamic flip-flop. Each of the dynamic logic circuits 110B, 110C, 110D, or 110E generates a pulse signal by using the clock signal CLK and determines a logic level of the input data DIN by using the clock signals CLK and CLKB, the pulse signal, and the data D.

The keeper circuit 10 D of FIG. 7 may be used together with the dynamic logic circuits 110B, 110C, 110D, and 110E. The dynamic logic circuits 110B, 110C, 110D, and 110E are examples for explaining an operation of the dynamic logic circuit 110 illustrated in FIG. 6 or 7. Thus, the keeper circuit 10D of FIG. 7 may be used together with each of the above dynamic logic circuits 110 to determine a logic level of the input data DIN by using the clock signal CLK and the data D.

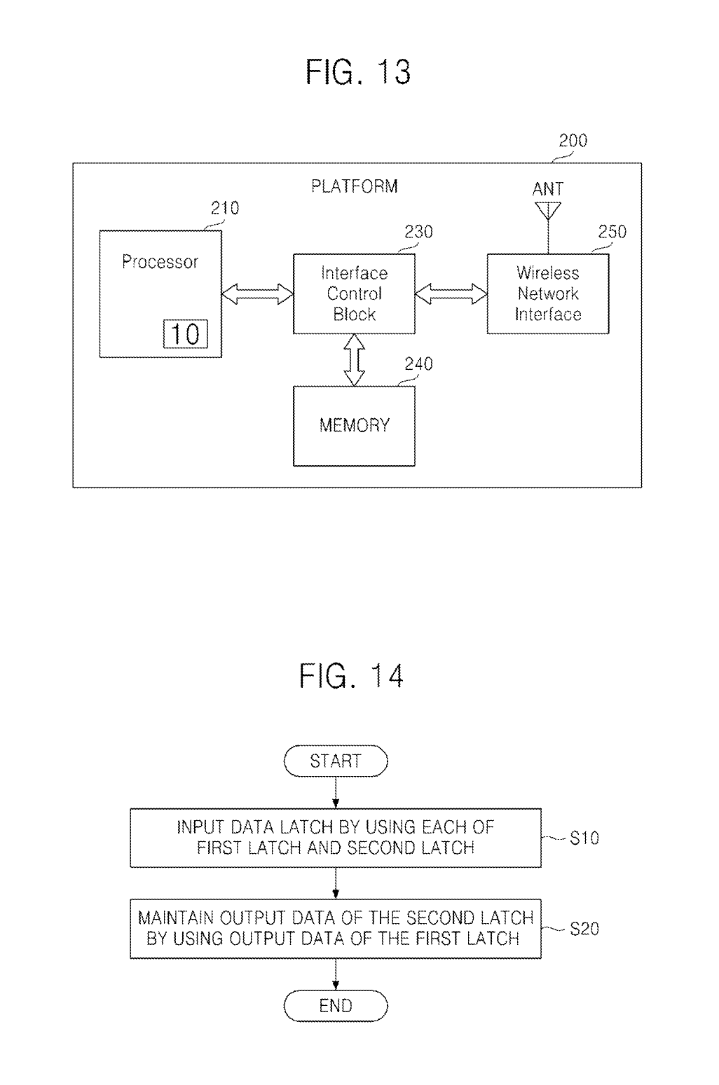

FIG. 13 is a clock diagram of an electronic device including a keeper circuit. A computer platform 200 may be used in an electronic device such as a computing system.

The electronic device may be a personal computer (PC) or a portable device. The portable device may be a laptop computer, mobile phone, smart phone, tablet PC, personal digital assistant (PDA), enterprise digital assistant (EDA), digital still camera, digital video camera, portable multimedia player (PMP), personal navigation device or portable navigation device (PND), handheld game console, e-book, etc.

The electronic device referred to as the computer platform 200 includes a processor (or central processing unit (CPU)) 210, an interface control block 230, a memory 240, and a wireless network interface 250. The electronic device may be a system on chip.

The processor 210 includes at least one core and at least one keeper circuit (e.g., keeper circuits 10, 10A, 10B, 10C, or 10D from FIGS. 1-3 and 5-7; collectively keeper circuit 10).

The processor 210 may include the data processing circuit 100 of FIG. 6 or 7.

The processor 210 may communicate with the memory 240 or the wireless network interface 250 through the interface control block 230. The interface control block 230 includes at least one circuit block performing a function of interface control. The control function includes memory access control, graphic control, input/output interface control, wireless network access control, or the like.

Each of the circuit blocks may be a separate chip or a part of the processor 210, or in the processor 210. The memory 240 may exchange data with the processor 210 through the interface control block 230. The wireless network interface 250 may connect the electronic device 200 to a wireless network, for example, mobile communication network or wireless local area network (LAN), through an antenna ANT.

FIG. 14 is a flow chart explaining an operation of the keeper circuit according to at least one example embodiment of the inventive concepts. Referring to FIGS. 1 through 14, each of the first latch 20 and the second latch 30 latches each output data determined by input data DIN in parallel during the evaluation state (S10).

According to at least one example embodiment, the second latch 30 maintains the output data DOUT of the second latch 30 by using the output data of the first latch 20 during the high-impedance state (S20).

The keeper circuit according to at least one example embodiment of the inventive concepts may reduce (or alternatively, prevent) distortion of the stored data caused by a coupling noise, even if a length of the interconnection wire becomes long such that the wire may be exposed to the coupling noise.

As described above, a keeper circuit according to an example embodiment of the inventive concepts may be used in digital circuits for latching data and the electronic devices including the digital circuit.

While the inventive concepts have been particularly shown and described with reference to example embodiments thereof, it will be understood by those of ordinary skill in the art that various changes in forms and details may be made therein without departing from the spirit and scope of example embodiments as defined by the following claims.

1. A keeper circuit comprising:
a first latch; and
a second latch, each of the first latch and the second latch being configured to latch output data determined by input data during an evaluation phase, and the second latch, during a high-impedance phase, being configured to maintain output data of the second latch using output data of the first latch.

2. The keeper circuit of claim 1, further comprising:
a load configured to be driven in response to the output data of the second latch.

3. The keeper circuit of claim 1, wherein
the first latch includes,
a first inverter configured to invert the input data during the evaluation phase;
a second inverter connected to an output node of the first inverter; and
a third inverter connected between an output node of the second inverter and the output node of the first inverter, and
the second latch includes,
a fourth inverter configured to invert the input data during the evaluation phase; and
a fifth inverter connected between the output node of the second inverter and an output node of the fourth inverter.

4. The keeper circuit of claim 3, wherein the third inverter and the fifth inverter are disabled during the evaluation phase and enabled in the high-impedance phase.

5. The keeper circuit of claim 1, wherein the first latch includes,
a first inverter configured to determine latch node data based on the input data and a clock signal;
a second inverter configured to invert the latch node data; and
a third inverter configured to latch the latch node data based on an output signal of the second inverter and the clock signal.

6. The keeper circuit of claim 5, wherein the second latch includes,
a fourth inverter configured to determine the output data of the second latch based on the input data and the clock signal; and
a fifth inverter configured to latch the output data of the second latch based on an output signal of the second inverter and the clock signal.

7. The keeper circuit of claim 6, wherein
the first inverter and the fourth inverter are enabled, and the third inverter and the fifth inverter are disabled during the evaluation phase; and
the first inverter and the fourth inverter are disabled, and the third inverter and the fifth inverter are enabled during the high-impedance phase.

8. An electronic device comprising:
a processor including a keeper circuit; and
a wireless network interface connected to the processor through an interface control block, the keeper circuit including,
a first latch, and
a second latch, each of the first latch and the second latch being configured to latch output data determined by input data during an evaluation phase, the second latch, during a high-impedance phase, being configured to maintain output data of the second latch using output data of the first latch.

9. The electronic device of claim 8, wherein the processor further includes a dynamic logic circuit configured to determine a logic level of the input data based on a clock signal and data.

10. The electronic device of claim 8, wherein the first latch includes,
a first inverter configured to determine latch node data based on the input data and a clock signal;
a second inverter configured to invert the latch node data; and
a third inverter configured to latch the latch node data based on an output signal of the second inverter and the clock signal.

11. The electronic device of claim 10, wherein the second latch includes,
a fourth inverter configured to determine the output data of the second latch based on the input data and the clock signal; and
a fifth inverter configured to latch the output data of the second latch based on an output signal of the second inverter and the clock signal.

12. The electronic device of claim 11, wherein
the first inverter and the fourth inverter are enabled, and the third inverter and the fifth inverter are disabled during the evaluation phase, and
the first inverter and the fourth inverter are disabled, and the third inverter and the fifth inverter are enabled during the high-impedance phase.

13. The electronic device of claim 8, wherein the electronic device is a system on chip.

14. The electronic device of claim 8, wherein the electronic device is a computing system.

15. A circuit, comprising:
a first latch configured to output a first signal based on at least one input signal during a first phase; and
a second latch configured to output a second signal based on at least one input signal during the first phase, and maintain the second signal during a second phase according to the first signal.

16. The circuit of claim 15, wherein the first and second phases correspond to an operation of a processor storing data to a memory element.

17. The circuit of claim 16, wherein if the at least one input signal is a logic state ‘1’, then the second latch maintains the second signal at a logic state ‘0’ during the second phase.

18. The circuit of claim 17, wherein if the at least one input signal is a logic state ‘0’, then the second latch maintains the second signal at a logic state ‘1’ during the second phase.

19. The circuit of claim 15, wherein the first latch includes first and second logic gates and an inverter, and the second latch includes third and fourth logic gates.

20. The circuit of claim 19, wherein
an input of the first logic gate and an input of the third logic gate are configured to receive the at least one input signal,
an output of the first logic gate is connected to an output of the second logic gate and an input of the inverter,
an output of the inverter is connected to an input of the second logic gate and an input of the fourth logic gate, and
an output of the third logic gate is connected to an output of the fourth logic gate, and the third logic gate is configured to output the second signal during the first phase, and the fourth logic gate is configured maintain the second signal during the second phase.
